(19) United States
(12) Patent Application Publication
(10) Pub. No.: US 2012/0142125 A1
(43) Pub. Date: Jun. 7, 2012

(54) PHOTOLUMINESCENCE IMAGING SYSTEMS FOR SILICON PHOTOVOLTAIC CELL MANUFACTURING

(75) Inventors: Thorsten Trupke, Coogee (AU); Ian Andrew Maxwell, Five Dock (AU); Juergen Weber, Coogee (AU); Robert Andrew Bardos, North Bondi (AU)

(73) Assignee: BT IMAGIN PTY LTD., Surry Hills ,New South Wales (AU)

(21) Appl. No.: 13/389,805

(22) PCT Filed: Aug. 16, 2010
(86) PCT No.: PCT/AU2010/001045

§ 371 Date: Feb. 10, 2012

(30) Foreign Application Priority Data
Aug. 14, 2009 (AU) 2009903823

(51) Int. Cl. G01N 21/64; H01L 21/66

(52) U.S. Cl. 438/16; 250/459.1; 257/E21.529; 250/208.1

(57) ABSTRACT

A method of photoluminence (PL) imaging of a series of silicon wafers, the method including the step of: utilizing incident illumination of a wavelength greater than 808 nm. The present invention further provides a method of analysing silicon semiconductor material utilising various illumination, camera and filter combinations. In some embodiments the PL response is captured by a MOSIR camera. In another embodiment a camera is used to capture the entire PL response and a long pass filter is applied to block a portion of the signal reaching the camera/detector.

### FIELD OF THE INVENTION

The present invention relates to photoluminescence imaging systems for use in silicon photovoltaic cell manufacturing.

### RELATED APPLICATIONS

The present application claims priority from Australian Provisional Patent Application Nos 2009903823, 2009903822 and 2009903813, each filed on 14 Aug. 2009, the contents of which are incorporated herein by reference.

### BACKGROUND OF THE INVENTION

Any discussion of the prior art throughout this specification should in no way be considered as an admission that such prior art is widely known or forms part of the common general knowledge in the field.

Photoluminescence (PL) imaging, performed for example using apparatus and methods disclosed in PCT Patent Application Publication No WO 2007/041758 A1 entitled ‘Method and System for Inspecting Indirect Bandgap Semiconductor Structure’ and incorporated herein by reference, has been shown to be of value for the rapid characterisation of silicon materials and devices, and silicon wafer-based photovoltaic (PV) cells in particular. As shown schematically in FIG. 1, luminescence 2 generated from a silicon wafer 4 with broad area photo-excitation from a source 6 of above-band gap light 8 can be imaged with a silicon CCD camera 10 via collection optics 11, with the system preferably including homogenisation optics 12 to improve the uniformity of the broad area excitation, and a long-pass filter 14 in front of the camera if the excitation light is within the detection band of the camera. The system may also include one or more filters 15 to select the wavelength range of the photo-excitation, if a broad band source is used. With relatively thin samples it is also possible to have the excitation source 6 and camera 10 on opposite sides of the sample 4 as shown in FIG. 2, in which case the sample itself can serve as a long-pass filter. However a long-pass filter 14 may still be required if a significant amount of stray excitation light, reflected for example off other components, is reaching the camera. Either way, the acquired PL image can be analysed with a computer 16 to obtain information on average or spatially resolved values of a number of sample properties including minority carrier diffusion length, minority carrier lifetime, dislocation defects, impurities and shunts, amongst others. The entire process can be performed in a matter of seconds or even fractions of a second depending on the quality of the silicon material and on design details of the imaging system.

The systems illustrated schematically in FIGS. 1 and 2 are stand-alone units, designed for research and development use for example in research institutions or in the R&D laboratory of a silicon wafer manufacturer or a PV cell manufacturer, where they may find application in inspecting selected wafers or PV cells for quality control purposes, or in a trouble-shooting role to help determine the type or origin of defects in a faulty batch of cells. However bulk silicon samples (e.g. ingots and bricks) as well as as-cut silicon wafers and PV cell precursors prior to passivation are extremely weak PL emitters because their minority carrier lifetime, on which the PL intensity depends, is limited by surface recombination. Image acquisition is therefore relatively slow for such samples, and while this is generally acceptable for R&D use or for routine inspection of bulk silicon samples, e.g. for identifying poor material quality regions prior to wafer sawing, inspection time is a critical factor if PL imaging is to be used for routine inspection of PV cells and precursors in a production environment, with current silicon wafer PV cell lines running at up to 3600 wafers per hour and with still faster lines expected.

Furthermore even in situations where inspection time is not a critical factor, the applicant has found that different types of silicon samples, e.g. as-cut wafers, surface textured wafers and finished PV cells, each have peculiarities such that existing PL imaging systems are not ideally suited to all of them. There is a need then for improved PL imaging systems, both in terms of measurement speed and in their suitability for characterising different types of silicon samples.

### SUMMARY OF THE INVENTION

It is an object of the present invention in its preferred form to provide effective photoluminescence imaging systems with low image acquisition times.

In accordance with a first aspect of the present invention, there is provided a method of photoluminescence imaging a silicon wafer, the method including the step of: utilising incident illumination of a wavelength greater than 808 nm. In some examples the illumination can be greater than 910 nm and even greater than 980 nm

The incident illumination can be filtered through a semiconductor material before being projected onto the silicon wafer, or a filter composed of a semiconductor material can be placed in front of the imaging equipment, the semiconductor material acting as a cut-off filter. In some embodiments the image can be captured utilising an indium gallium arsenide imaging device or a MOSIR imaging device.

In accordance with a further aspect of the present invention, there is provided a method of photoluminescence imaging of surface damaged silicon wafers, the method including the step of: imaging the wafer with long wavelength excitation to generate substantially more photoluminescence from an internal portion of the wafer than the surface damaged portion of the wafer.

In some embodiments, the excitation wavelength can be substantially longer than 808 nm The excitation wavelength is preferably longer than 910 nm, more preferably longer than 980 nm. In some embodiments, a sharp transition long pass filter having a cut-off wavelength longer than the excitation wavelength can be utilised in imaging the wafer. The long pass filter preferably includes a semiconductor material.

The method of the preferred embodiment can further include the step of subsequently surface etching the wafer.

In some embodiments, the photoluminescence imaging occurs substantially within 100 milliseconds, preferably within 10 or 1 milliseconds, depending upon requirements.

In accordance with another aspect of the present invention there is provided a method of analysing a silicon material comprising subjecting the silicon material to a sufficient level of illumination to achieve a photoluminescence response, capturing the photoluminescence response as an image with a camera wherein: illumination is applied at a ‘high intensity’ as herein defined or at a wavelength greater than 808 nm, and the camera captures all or substantially all of the photoluminescence response in the photoluminescence emission spectrum.

In accordance with another aspect of the present invention, there is provided a method of capturing a photoluminescence response from a silicon material comprising using a MOSIR based camera.

In accordance with another aspect of the present invention, there is provided a method of capturing a photoluminescence response from a semiconductor material, wherein the semiconductor material is illuminated with excitation light within the signal band detectable by the camera used to capture the photoluminescence response, a long pass filter being provided to block illumination and stray excitation signals from the camera. Preferably, the filter is a semiconductor filter.

### BRIEF DESCRIPTION OF THE DRAWINGS

Benefits and advantages of the present invention will become apparent to those skilled in the art to which this invention relates from the subsequent description of exemplary embodiments and the appended claims, taken in conjunction with the accompanying drawings, in which:

FIG. 1 illustrates schematically a prior art system for PL imaging of a semiconductor sample;

FIG. 2 illustrates schematically another prior art system for PL imaging of a semiconductor sample;

FIGS. 3(a) and 3(b) illustrate schematically in side view and front view an in-line PL imaging system;

FIGS. 4(a) and 4(b) illustrate schematically in side view and front view another in-line PL imaging system;

FIG. 5 shows a typical luminescence spectrum emitted by a crystalline silicon wafer (left axis) and the absorption coefficient of crystalline silicon (right axis) at room temperature;

FIG. 6 shows the fraction of silicon PL emission that can be detected with a silicon camera, compared with the total PL emission; and

FIG. 7 shows a PL image of an as-cut multicrystalline silicon wafer.

### DETAILED DESCRIPTION

Preferred embodiments of the invention will now be described, by way of example only, with reference to the accompanying drawings.

With its known ability to measure several material parameters of interest to wafer and PV cell manufacturers, photoluminescence (PL) imaging has many existing and potential applications in the PV cell manufacturing industry. PL imaging is already used in stand-alone test and measurement tools, e.g. to investigate poorly performing cells or as a random check of incoming wafer quality, and we believe there are realistic prospects for developing in-line PL imaging systems with a variety of capabilities including wafer sorting and binning, process control feedback (e.g. to correct a defective processing stage) or feed-forward (e.g. to adjust a processing stage in preparation for a different grade of feedstock), either with direct machine control or via a human operator.

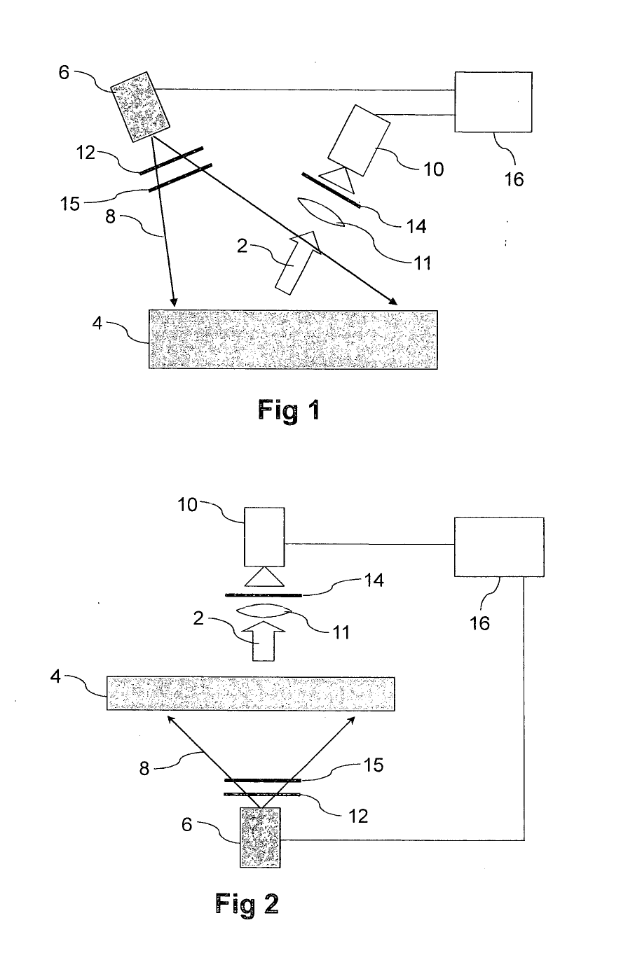

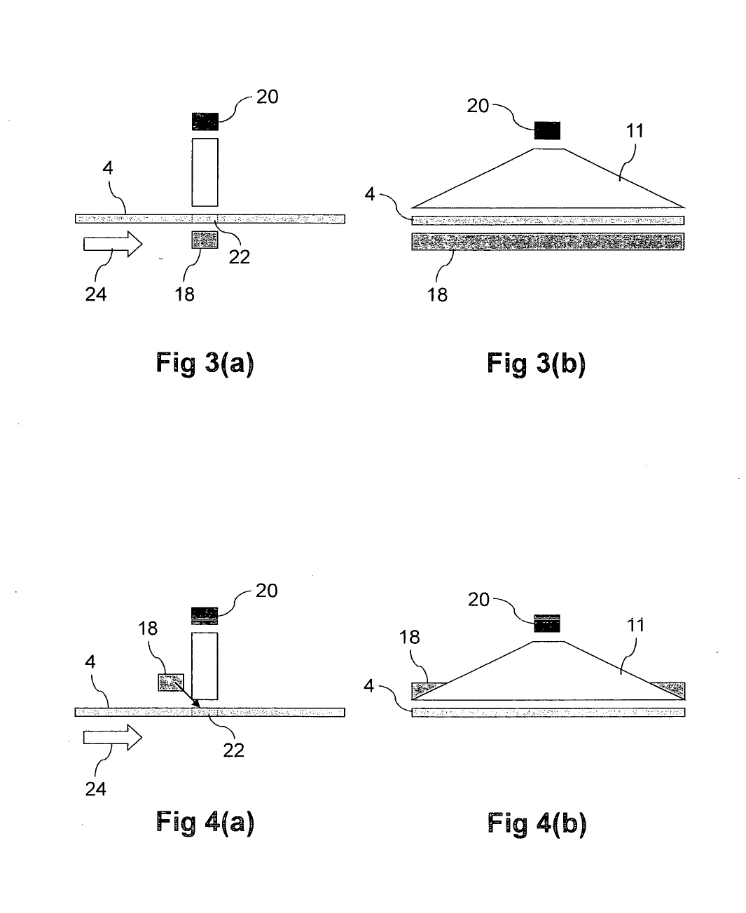

FIGS. 3(a) and 3(b) show in side view and front view respectively a schematic of an in-line PL imaging system comprising a linear illumination source 18 such as an IR LED bar and a line camera 20 such as a linear silicon CCD array positioned on either side of a silicon wafer 4, with a system of collection optics 11 for focusing the PL emission from the full width of the wafer into the line camera. The line camera acquires a series of line images of the illuminated stripe 22 as the wafer passes through as indicated by the arrow 24, and an image of the full wafer area constructed by a computer (not shown). FIGS. 4(a) and 4(b) show a similar in-line system with the illumination source 18 and the line camera 20 located on the same side of the sample wafer 4. It will be appreciated that several of the other components illustrated in the ‘area imaging’ systems of FIGS. 1 and 2, such as homogenisation optics, excitation filters and signal filters, will also be present as required.

Each combination of sample type (e.g. as-cut wafer, partially processed PV cell or completed PV cell) and imaging type (e.g. area or line imaging) will have its own desired set of performance specifications and cost constraints which must be met to produce a cost-effective and reliable system. Measurement speed is clearly an important specification for in-line imaging applications, although it will be seen that there are many situations where other performance specifications are equally or more important. For exemplary purposes we will concentrate on as-cut wafers, textured wafers and post-passivation wafers to explain some of the compromises that must be made when designing PL imaging systems. One specific configuration is unlikely be optimal for all types of silicon samples, and several trade-offs are required if one wishes to design a general purpose system. It will be seen that in many cases the ‘design rules’, i.e. the required combinations of excitation sources (both in terms of wavelength and intensity) and cameras, as well as filters that may be required especially if the excitation and emission bands are close to each other, are non-obvious. Furthermore the component cost must always be borne in mind when designing systems for industrial application. Henceforth in this specification we will only describe and show images acquired with area imaging cameras, but it will be appreciated that many of the design considerations, e.g. illumination wavelength, filtering and camera type, apply equally well to line-scanning imaging systems.

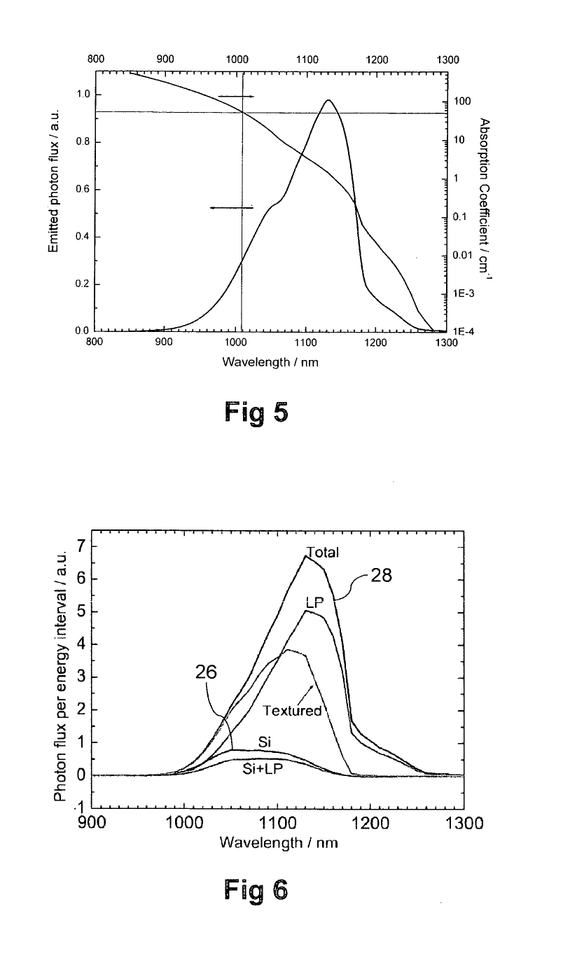

We show in FIG. 5 a typical band-to-band luminescence spectrum emitted by a crystalline silicon wafer (left axis) and the absorption coefficient of crystalline silicon (right axis) at room temperature. It can be seen that the absorption of silicon becomes insignificant at wavelengths above 1100 nm or so, and at first impression it may appear that a shorter excitation wavelength would be better for measurement speed because it would increase the carrier generation rate. However shorter wavelength excitation is absorbed closer to the surface, so that for as-cut wafers the PL will be generated from the saw-damaged surface layer which is not particularly useful because the damaged layer is removed at the saw damage etch stage and is a poor indicator of the underlying material quality.

For PL imaging to provide an early stage indicator of future cell performance, it is better to use longer wavelength excitation, e.g. 850 nm, 910 nm or 980 nm rather than visible light, to generate PL emission from the interior of the wafer. Even for silicon wafers with better surface quality, e.g. passivated wafers, it can be advantageous to use longer illumination wavelengths to obtain a truer picture of the bulk properties. Consequently when performing PL imaging of silicon samples, it is preferred to generate the PL emission with illumination wavelengths longer than 800 nm, preferably longer than 910 nm, and most preferably around 980 nm or longer. Therefore, in the preferred embodiments, longer wavelength light is utilised so as to generate PL emission from the interior of the wafer.

Longer illumination wavelengths may however generate less PL because of the lower absorption, resulting in increased measurement time for a given excitation intensity, signal-to-noise ratio and detection system. For as-cut wafers the achievable PL emission is further limited by the fact that their effective lifetime is low, of order 1 μs for multicrystalline silicon, because of rapid surface recombination. Under the assumption of low injection conditions, the PL signal I_{PL} is to a good approximation proportional to the effective minority carrier lifetime τ_{eff}, which clearly makes it more difficult to generate a measurable signal from an as-cut wafer than from a passivated multicrystalline wafer (τ_{eff}10 μs) or a high quality passivated monocrystalline wafer (τ_{eff}˜1 ms) for example.

One means to enhance the measurement speed is to use more intense illumination to generate more charge carriers and therefore more PL photons. Although the PL signal does not always scale linearly with illumination intensity, especially at high intensities where the carrier lifetime becomes injection level dependent, it is in general true that more intense illumination produces a larger PL signal. Furthermore the dependence is essentially linear over a wider illumination intensity range for as-cut wafers, because the effective carrier lifetime is essentially determined by surface recombination. While there may be a preference when performing PL imaging of PV cells close to or at end of line to use modest illumination intensities of order 1 Sun (100 mW/cm²) to more closely match normal operating conditions, this is less important in the early stages of cell production so that high illumination intensities are generally preferable for generating PL from as-cut wafers.

Turning now to consideration of various camera technologies, we note firstly that most commercial PL imaging systems currently used in PV R&D or manufacturing use silicon CMOS or CCD cameras. Inspection of the silicon absorption and luminescence spectra shown in FIG. 5 shows that it is not necessarily an obvious choice to use a silicon camera to measure the luminescence from silicon samples, because the majority of the ˜900 to 1300 nm luminescence band is beyond the detection range of a silicon camera (as indicated by the absorption spectrum). The actual fraction of silicon PL photons that could be detected by a silicon camera is represented by the curve 26 in FIG. 6, compared to the total available signal represented by the curve 28, and we estimate that only about 5% of the total signal can be detected. Although there are many pragmatic reasons for choosing silicon cameras, such as cost and the fact that it is a well developed and reliable technology available in several formats (e.g. 1024×1024 pixel arrays) and with relatively large pixels (larger pixels mean higher count rates and therefore faster measurements), and although they do have some more subtle benefits to be described below, an alternative camera technology able to capture the entire PL spectrum, rather than 5%, is clearly worth considering. Assuming similar quantum efficiencies, such a camera can offer an immediate 20× increase in measurement speed.

Another issue with silicon cameras, particularly when using longer excitation wavelengths to generate PL from the non-surface portion of a sample, is that the excitation light (e.g. 950 nm) is close to the detectable signal band as represented by the curve 26 in FIG. 6, meaning that a long pass filter with a sharp transition from low to high absorption is required in front of the camera to block the excitation without blocking the detectable PL to any great extent. Furthermore the rejection ratio should be large because, for indirect band gap semiconductors such as silicon, the illumination intensity is orders of magnitude greater than the PL intensity. We have found that semiconductor materials are effective in this regard because they exhibit a sharp change in transmission at their band edge; several examples of semiconductor materials that may be used as filters are listed in Table 1. We note that a band stop filter could also be used in this context, so long as the excitation band is within the low transmission region. It will be appreciated that if a camera sensitive to the entire PL spectrum were used, this filtering is less critical because there can be a wider separation between the excitation and detection bands.

Two camera technologies sensitive across the full silicon PL emission spectrum are InGaAs and a recently developed technology known as ‘MOSIR’ that uses an InGaAs or InGaAsP photocathode that creates electrons in a vacuum tube in response to near IR photons and accelerates them onto a silicon focal plane array (FPA) device (a CCD or CMOS sensor). Both are sensitive from approximately 900 nm to 1700 nm or longer wavelengths depending on the precise composition of the InGaAs, and could therefore also be used, if desired, to study PL bands in the 1500 to 1700 nm region that have been assigned to various defects in silicon (see for example P. Edelman et al ‘Photoluminescence and minority carrier diffusion length imaging in silicon and GaAs’, Semiconductor Science and Technology 7 (1992), A22-A26).

Another general advantage of MOSIR and InGaAs cameras over silicon cameras is that if the excitation wavelength is considerably shorter than 900 nm then there may be no need for a long pass filter to prevent the excitation from reaching the camera. Furthermore even if a long pass filter is required, e.g. when using an excitation wavelength longer than 900 nm for as-cut wafers, the steepness of the filter transmission edge is less critical because there is plenty of detectable signal in the longer portion of the PL spectrum.

| | Band gap (eV) | wavelength | Dopants (p- | Dopants | Undoped |
|---|---|---|---|---|---|
| Material | @ 300K | (nm) | type) | (n-type) | type |
| Lead(II) selenide | 0.27 | 4593 | | | |
| Lead(II) telluride | 0.29 | 4276 | | | |
| Indium(III) arsenide | 0.36 | 3444 | | | |
| Lead(II) sulfide | 0.37 | 3351 | | | |
| Germanium | 0.67 | 1851 | | | |
| Gallium antimonide | 0.7 | 1771 | Si, Ge | Te | p |
| Silicon | 1.11 | 1117 | B, Al, Ga, In | P, As, Sb, Bi | |
| Indium(III) phosphide | 1.35 | 919 | Zn, Fe | S, Sn | n |
| Gallium(III) arsenide | 1.42 | 873 | Zn, Cr | Si, Te | Sl/n |
| Cadmium telluride | 1.49 | 832 | P, As, Sb, Bi | In, Cl, I | n |
| Aluminium antimonide | 1.6 | 775 | Si, Be | Te | p |
| Cadmium selenide | 1.73 | 717 | | | |
| Aluminium arsenide | 2.16 | 574 | | | |
| Zinc telluride | 2.25 | 551 | | | |
| Gallium(III) phosphide | 2.26 | 549 | Zn, Cr | S | n |
| Cadmium sulfide | 2.42 | 512 | | | |
| Aluminum phosphide | 2.45 | 506 | | | |
| Zinc selenide | 2.7 | 459 | | | |
| Silicon carbide | 2.86 | 434 | | | |
| Zinc oxide | 3.37 | 368 | | | |
| Gallium(III) nitride | 3.4 | 365 | | | |
| Zinc sulfide | 3.6 | 344 | | | |
| Diamond | 5.5 | 225 | | | |
| Aluminium nitride | 6.3 | 197 | | | |
| Gallium(II) sulfide | 2.5 (@ 295K) | 495 | | | |
| Indium Gallium Nitride | 0.7-3.37 | | Mg | Si | |
| Copper Indium Gallium Di- | 1.04-1.67 | | Na | Zn, Cd | p (also n) |
| Selenide | | | | | |
| Zinc telluride | 2.24 | 553 | N | Al, Ga, In | p |
| Gallium Indium Phosphide | 2.26-1.35 | | Mg, Zn | Si, S, Se, Te | |
| Aluminium Gallium Arsenide | 1.42-2.17 | | Zn, Be | Si | |
| Aluminium Gallium Indium | | | Zn, C, Be | | |
| Arsenide | | | | | |
| Gallium Indium Arsenide | 0.36-1.42 | | Mg, Zn, Cd, | Sn, Ge, Si, | |
| | | | Mn | C | |
| Gallium Arsenide Antimonide | 0.7-1.42 | | Zn, Si, Ge | S, Se, Te | |
| Gallium Indium Arsenide | 0.36-2.26 | | Mg, Zn, Cd, | Sn, Ge, Si, | |
| Phosphide | | | Mn, Be | Te, S | |

For imaging purposes the MOSIR technology, with its combination of InGaAs and Si detection, is advantageous over simple InGaAs arrays in some respects. Firstly the Si FPA is a mature technology with a larger number of pixels than currently available with InGaAs, meaning greater spatial resolution. Secondly the readout noise is small because of the ˜100× gain between the photocathode and the Si FPA. For example if ten photoelectrons are generated at the photocathode, they will produce ˜1000 electrons in the Si FPA. If the readout noise is 50 electrons (typical for CMOS) then the signal/noise is 20:1. That is, the noise referred back to the input is less than a single photoelectron, meaning that the frame averaging is almost noise-less. Hereinafter we will use the terminology ‘MOSIR camera and the like’ to describe any imaging device sensitive across the full silicon PL emission spectrum, i.e. 900 to 1300 nm.

In certain types of silicon samples, particularly PV wafers where the surface has been textured to trap incident light to enhance cell efficiency, the ability of MOSIR cameras and the like to capture the entire silicon PL emission spectrum may impart a greater benefit than the 20× enhancement mentioned above. To explain, the large refractive index contrast at the silicon/air interface means that a large fraction of the luminescence photons generated isotropically by radiative recombination does not escape from the silicon on the first encounter, but is internally reflected. Within this fraction, shorter wavelength photons will tend to be re-absorbed while longer wavelength photons will propagate laterally through the wafer for some distance before being either re-absorbed or scattered out of the surface, possibly reaching the imaging camera. The out-scattering is enhanced by the rough surface of textured wafers, so that the overall PL spectrum emitted from a textured wafer is strongly enhanced at longer wavelengths compared to the emission from a planar wafer. A silicon camera is unable to benefit from this enhanced long wavelength signal, but for MOSIR cameras and the like we estimate that this effect gives a further 3× increase in detectable signal from typical textured wafers.

Despite the obvious attractions of a camera technology that captures all or substantially all of the band-to-band PL emission spectrum from silicon, particularly in terms of measurement speed, there are more subtle factors that require compromises to be made when imaging silicon wafers, particularly textured wafers where the light trapping effect that enhances the long wavelength PL signal also has a substantial drawback. Images acquired using longer wavelength PL have decreased spatial resolution because of a ‘smearing’ effect caused by trapping and lateral transport of longer wavelength photons inside the sample wafer. To explain, because longer wavelength PL photons trapped within a textured wafer can propagate laterally for distances much larger than the wafer thickness before being scattered out of the surface, they can emerge from a sample and be detected some distance from where they were generated. This image smearing effect, which is to be distinguished from the blurring effect caused by carrier transport through the emitter layer of a PV cell, can be so severe as to mask the presence of fine features such as dislocations or cracks, or increase the difficulty of distinguishing one type of feature from another, especially if the differences in count rate between ‘good’ quality areas (higher count rate) and ‘bad’ quality areas are relatively small. PL imaging systems with Si cameras are less affected by this image smearing because they are insensitive to the longer wavelength portion of the PL spectrum, although some image smearing also occurs because PL photons close to the detection limit can be scattered laterally with the Si-CCD chip (or similar), resulting in photons being detected in the wrong pixel.

A major consequence of the smearing effect is that the choice of an appropriate camera technology for PL imaging of silicon is by no means obvious, as there will be a compromise between spatial resolution and measurement speed. If measurement speed is the primary consideration then an imaging system with a MOSIR camera or the like may be preferable, although we note that the measurement speed of a system with an Si camera can be enhanced somewhat by pixel binning; if spatial resolution is already compromised by image smearing then there may be little more to lose by pixel binning. As described in a PCT Patent Application entitled ‘Photoluminescence imaging of surface textured wafers’ and filed on even date by the present applicant, image smearing can be substantially eliminated, resulting in superior spatial resolution, by using a 1000 nm short pass filter to reject long wavelength PL emission. This negates the long wavelength sensitivity advantage of systems with MOSIR cameras or the like, but could be offered as an option, e.g. on a filter wheel, for situations where greater spatial resolution is required.

A compromise position could also be reached, with the short pass cut-off wavelength chosen according to an acceptable amount of image smearing.

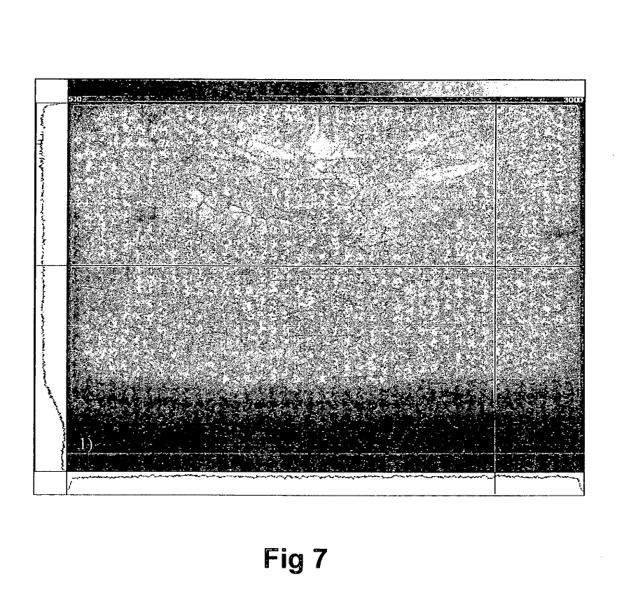

When assessing the possible impact of smearing on image resolution, it is also worth considering what sort of wafers are being imaged to determine what level of detail can be expected even with optimal spatial resolution (i.e. no smearing). To illustrate this point, FIG. 7 shows a PL image of an as-cut multicrystalline silicon wafer where the PL was generated with full area illumination from an 805 nm diode laser and captured with a 1 megapixel silicon CCD camera. The PL image has an area of low luminescence intensity near the bottom edge, caused by a low material quality (and hence low carrier lifetime) region as typically found in multicrystalline silicon wafers cut from near the sides of a block, with the remainder being of relatively homogeneous luminescence intensity in which grain structure can be seen only faintly. A consequence of the homogeneous PL emission in this second region, which is due to the fact that in as-cut wafers the effective carrier lifetime is limited by surface recombination, is that there is little spatial detail to be discerned, so that the image smearing experienced by MOSIR cameras and the like may be of little concern. A cell manufacturer would not expect a cell made from an ‘edge’ wafer such as the one shown in FIG. 7 to be as efficient as a cell made from a wafer cut from the interior of a block, and if the only goal of as-cut wafer inspection is to sort incoming wafers into quality bins on this basis then a PL imaging system with a MOSIR camera or the like, a longer wavelength illumination source (e.g. 950 nm) and an appropriate long pass filter (e.g. cut-off at 1000 nm) would be a good design choice. The longer wavelength illumination will generate PL from below the saw damaged surface layer, and the broad sensitivity of MOSIR cameras and the like enables line speed inspection (e.g. one wafer per second) despite the weak PL emission of as-cut wafers.

On the other hand if a cell manufacturer wishes to use PL imaging to investigate, say, the density distribution of electrically active defects such as dislocations across a PV cell or partially processed wafer, the spatial resolution should be as high as possible so that the fine dislocation networks can be resolved and quantified with edge detection techniques or other image processing algorithms. In this situation a silicon camera would be a better design choice, with the PL emission short pass filtered if necessary to further reduce image smearing. Provided the sample is a finished cell or a post-passivated wafer, i.e. has a reasonable to high effective lifetime, it is more straightforward to achieve a measurement time of the order of one second or less despite the lesser sensitivity of silicon cameras across the PL emission spectrum. Furthermore a shorter excitation wavelength can be used for these samples, which is easier to separate from the camera input with filters. More powerful illuminators can also be of value, not just to generate more signal but also to produce sharper images; as explained in T. Trupke et al ‘Progress with luminescence imaging for the characterization of silicon wafers and solar cells’, 22^{nd} European Photovoltaic Energy Conference, Milan, September 2007, higher illumination intensity suppresses the blurring caused by lateral carrier transport through the emitter layer. For the purposes of this specification, we define ‘high intensity’ illumination as being greater than 50 Suns (5 W/cm²) on a wafer.

The above discussion of differing requirements for PL imaging systems depending on the type of sample being inspected and on the purpose of the inspection illustrates that the design of suitable PL imaging systems is not only not straightforward, but is in some respects counter-intuitive. For example despite the fact that the radiative efficiency of silicon is exceedingly low, suggesting that one should use a camera that can capture the entire silicon PL emission system, there are several instances where it is preferable to discard a considerable fraction of the PL emission. This applies particularly to MOSIR cameras and the like, e.g. because of image smearing, which goes against the perceived wisdom that when measuring a weak broad band signal it is best to use a camera sensitive across the entire band. In some situations it is necessary to discard the short wavelength portion of the silicon PL emission, e.g. when long wavelength excitation is preferred, while in other situations it is necessary to discard the long wavelength portion, e.g. if spatial resolution is the key requirement. In yet other situations it may be necessary to discard both short and long wavelength portions, e.g. with a band pass filter, leaving a very limited spectral region available for measurement.

Some users may require a system designed for one specific application, e.g. high spatial resolution imaging of finished PV cells, or quality binning of incoming wafers at line speed. Other users may require a general purpose system, in which case several compromises will have to be made. The applicable range of a system can be extended by providing of a number of filters for the chosen camera, or by providing two or more excitation sources (e.g. 810 nm and 950 nm lasers), albeit at extra cost.

Although the present invention has been described with particular reference to certain preferred embodiments thereof, variations and modifications of the present invention can be effected within the spirit and scope of the following claims.

1. A method of acquiring a photoluminescence image of a silicon wafer, the method including the step of:
utilising incident illumination with a wavelength greater than 808 nm to generate the photoluminescence.

2. A method as claimed in claim 1 wherein the wavelength of the incident illumination is greater than 910 nm.

3. A method as claimed in claim 1 wherein the wavelength of the incident illumination is greater than 980 nm.

4. A method as claimed in claim 1 wherein said incident illumination is filtered through a semiconductor material before being projected onto said silicon wafer.

4a. (canceled)

5. A method as claimed in claim 4 wherein said semiconductor material acts as a cut-off filter.

6. A method as claimed in claim 1 wherein said photoluminescence image is acquired with an indium gallium arsenide imaging device.

7. A method as claimed in claim 1 wherein said photoluminescence image is acquired with a MOSIR imaging device.

8. A method of photoluminescence imaging of a surface damaged silicon wafer, the method including the step of:
illuminating the wafer with long wavelength excitation to generate substantially more photoluminescence from an internal portion of the wafer than from the surface damaged portion of the wafer.

9. A method as claimed in claim 8 wherein the wavelength of said long wavelength excitation is substantially longer than 808 nm.

10. A method as claimed in claim 9 wherein the wavelength of said long wavelength excitation is longer than 910 nm.

11. A method as claimed in claim 10 wherein the wavelength of said long wavelength excitation is longer than 980 nm.

12. A method as claimed claim 8 wherein a sharp transition long pass filter having a cut off wavelength longer than the excitation wavelength is utilised in imaging the wafer.

13. A method as claimed in claim 12 wherein said long pass filter includes a semiconductor material.

14. A method as claimed in claim 8 further comprising the step of subsequently surface etching the wafer.

15. A method as claimed in claim 8 wherein the photoluminescence imaging occurs substantially within 100 milliseconds.

16. A method as claimed in claim 15 wherein the photoluminescence imaging occurs substantially within 10 milliseconds.

17. A method as claimed in claim 16 wherein the photoluminescence imaging occurs substantially within 1 millisecond.

18. A method of analysing a silicon material, the method comprising subjecting the silicon material to a sufficient level of illumination to achieve a photoluminescence response, capturing the photoluminescence response as an image with a camera wherein:
i) illumination is applied at a ‘high intensity’ as herein defined, or at a wavelength greater than 808 nm, and
ii) the camera captures all or substantially all of the PL response in the PL emission spectrum.

19. A method of capturing a photoluminescence response from a silicon material comprising using a MOSIR based camera.

20. A method of capturing a photoluminescence response from a semiconductor material, wherein the semiconductor material is illuminated with excitation light within the signal band detectable by the camera used to capture the photoluminescence response, a long pass filter being provided to block illumination and stray excitation signals from the camera.

21. A method as claimed in claim 20 wherein the filter is a semiconductor filter.

22. A method as claimed in any one of claims 1 wherein a filter composed of a semiconductor material is placed in front of the imaging device used to acquire the photoluminescence image.
